(19) United States
(12) Patent Application Publication
(10) Pub. No.: US 2012/0055787 A1
(43) Pub. Date: Mar. 8, 2012

(54) Sputtering Target and Method of Processing a Sputtering Target

(75) Inventors: Akira Ohba, Chiba (JP); Junichi Nitta, Chiba (JP); Nobuhiro Harada, Chiba (JP); Poong Kim, Chiba (JP); Yasuo Mihara, Chiba (JP)

(73) Assignee: ULVAC, INC., Kanagawa (JP)

(21) Appl. No.: 13/257,689

(22) PCT Filed: May 18, 2010
(86) PCT No.: PCT/JP2010/003326

§ 371 Date: Sep. 20, 2011

(30) Foreign Application Priority Data
May 28, 2009 (JP) 2009-129095

(51) Int. Cl. C23C 14/34; C23C 8/00; C23C 14/14

(52) U.S. Cl. 204/298.13; 204/298.12; 148/240

(57) ABSTRACT

[Object] To provide a sputtering target allowing component metals to be separated from each other by a simple process and a method of processing the sputtering target.

[Solving Means] A method of processing a sputtering target according to the present invention performs a hydrogen embrittlement process with respect to a sputtering target 1 including a first target portion 3 made of a first material being a non hydrogen embrittlement material and a second target 4 portion made of a second material being a hydrogen embrittlement material, which are bonded to each other, to thereby separate from the sputtering target 1 the second target portion 4, collects the second material, and collects the first material. By utilizing difference in hydrogen embrittlement between the first material and the second material, the first material and the second material are separated from each other and collected. It is possible to efficiently collect the first material and the second material.

### TECHNICAL FIELD

The present invention relates to a sputtering target including constituent materials easy to be collected and a method of processing the sputtering target.

### BACKGROUND ART

A sputtering process being one of the film-forming methods is a film-forming method in which particles each having high energy is caused to collide with a top surface (surface to be sputtered) of a sputtering target (hereinafter, referred to as target) made of a metal or the like, to thereby deposit atoms sputtered from the target on the substrate. In the sputtering, in order to form a uniform film on the top surface of the substrate, the target having some large area to be sputtered has to be used. The used target subjected to the sputtering can be recycled as a metal material. In particular, in recent years, along with an increase of the area of the substrate (film-forming object) of an FPD (Flat Panel Display) or the like, an increase of the value of a film-forming material, and the like, it has been more important to recycle the used target material.

In general, in the sputtering process, according to the above-mentioned principle, the composition of film on the substrate and the composition of the target correspond to each other. Therefore, in a case of forming a film of an alloy, a target made of an alloy is used. However, the target made of the alloy is used as one that has a fixed alloy composition because it is difficult to separate metals (component metals) constituting the alloy from each other. Thus, there is a problem that as compared to a target made of a single metal, its recycle value is significantly lower.

On the other hand, in the case of forming the film of the alloy, also by sputtering a target including a plurality of target pieces made of component metals, which are bonded to each other, the film of the alloy can be formed on the substrate. For example, Patent Document 1 discloses a method of forming a target by solid-state-diffusion-bonding target materials to each other. It is described that in this method, in such a way that a hot isostatic press or the like is used to solid-state-diffusion-bond the target materials made of the same kind or different kinds of materials to each other, a large-area target with those materials being bonded to each other with a high strength can be obtained.

### CITED DOCUMENT

### Patent Document

Patent Document 1: Japanese Patent Application Laid-open No. 2004-204253 (paragraph [0012])

### DISCLOSURE OF THE INVENTION

### Problem to be Solved by the Invention

However, in the target formed by using the method described in Patent Document 1, a plurality of target materials are strongly bonded to each other by the solid-state diffusion bonding. Therefore, in a case of a target with a plurality of kinds of target materials being solid-state-diffusion-bonded to each other, machining or the like is needed for performing the separation for each component metal, which makes working troublesome. On the other hand, in a case of boding the target materials by a bonding method by which the target materials are bonded to each other with a low bonding strength for easiness of the separation of the target materials for each component metal, it is conceivable that generation of particles due to arc discharge at bonding positions, deformation due to thermal expansion of the target materials, and the like occur.

In view of the above-mentioned circumstances, it is an object of the present invention to provide a sputtering target allowing component metals to be separated from each other by a simple process and a method of processing the sputtering target.

### Means for Solving the Problem

In order to the above-mentioned object, a method of processing a sputtering target according to an embodiment of the present invention includes performing a hydrogen embrittlement process with respect to a sputtering target including a first target portion made of a first material being a non hydrogen embrittlement material and a second target portion being a second material made of a hydrogen embrittlement material, which are bonded to each other, to thereby separate from the sputtering target the second target portion.

The second material is collected.

The first material is collected.

In order to the above-mentioned object, a sputtering target according to an embodiment of the present invention is a sputtering target including a surface to be sputtered, for forming a thin film made of the alloy, and includes a first target portion and a second target portion.

The first target portion is made of a first material being a non hydrogen embrittlement material not to be embrittled in hydrogen atmosphere, and forms a part of the surface to be sputtered.

The second target portion is made of a second material being a hydrogen embrittlement material to be embrittled in the hydrogen atmosphere, is bonded to the first target portion, and forms another part of the surface to be sputtered.

### BRIEF DESCRIPTION OF DRAWINGS

FIG. 1 A plane view showing a sputtering target according to a first embodiment.

FIG. 2 A perspective view showing the sputtering target according to the first embodiment.

FIG. 3 Views describing a method of manufacturing the sputtering target according to the first embodiment.

FIG. 4 A view showing a schematic configuration of a sputtering apparatus using the sputtering target according to the first embodiment.

FIG. 5 A plane view showing a sputtering target according to a second embodiment.

FIG. 6 A perspective view showing the sputtering target according to the second embodiment.

FIG. 7 Views describing a method of manufacturing the sputtering target according to the second embodiment.

FIG. 8 Views showing a sputtering target according to Modification 1.

FIG. 9 Views showing a sputtering target according to Modification 2.

FIG. 10 Views showing a sputtering target according to Modification 3.

### BEST MODE(S) FOR CARRYING OUT THE INVENTION

A method of processing a sputtering target according to an embodiment of the present invention includes performing a hydrogen embrittlement process with respect to a sputtering target including a first target portion made of a first material being a non hydrogen embrittlement material and a second target portion made of a second material being a hydrogen embrittlement material, which are bonded to each other, to thereby separate from the sputtering target the second target portion.

The second material is collected.

The first material is collected.

By the hydrogen embrittlement process, the second target portion is embrittled and fractured. On the other hand, the first target portion is not embrittled, and hence remains as it is. Thus, it is possible to selectively collect the first material and the second material. The second target portion is fractured due to the hydrogen embrittlement, and hence even in the case where the first target portion and the second target portion are strongly bonded to each other, or in the case where the first target portion is constituted of fine target pieces, it is possible to readily collect them. As described above, the method of processing the sputtering target according to this embodiment, it is possible to selectively collect the first material and the second material, or the first materials of the different kinds and the second material. That is, by a simple process, component metals can be separated from each other.

The step of performing the hydrogen embrittlement process may include keeping the sputtering target in the hydrogen atmosphere at a first temperature, and then changing the first temperature to a second temperature lower than the first temperature.

At the first temperature, hydrogen is absorbed by the second target portion, and at the second temperature, the absorbed hydrogen is gasified and expanded. Thus, the second target portion is embrittled. That is, the second target portion can be hydrogen-embrittled, and the first target portion can be prevented from being embrittled, the second target portion and the first target portion being included in the same sputtering target.

A sputtering target according to an embodiment of the present invention is a sputtering target including a surface to be sputtered, for forming a thin film made of an alloy, and includes a first target portion and a second target portion.

The first target portion is made of a first material being a non hydrogen embrittlement material not to be embrittled in the hydrogen atmosphere, and forms a part of the surface to be sputtered.

The second target portion is made of a second material being a hydrogen embrittlement material to be embrittled in hydrogen atmosphere, is bonded to the first target portion, and forms another part of the surface to be sputtered.

When such a sputtering target is used for sputtering, the thin film made of the alloy of the first material and the second material is formed on the substrate. Depending on the area that is occupied by the first target portion and the second target portion on the surface to be sputtered, the composition of the alloy thin film can be controlled. In the sputtering target, by performing the hydrogen embrittlement process as described above, the second target portion is hydrogen embrittlement, and hence the first target portion and the second target portion are separated from each other. Thus, it is possible to collect the first material and the second material while discriminating the first material and the second material from each other.

The first target portion may be made of a plurality of first target pieces, the second target portion may be made of a plurality of second target pieces, and each of the second target pieces may be interposed between the plurality of first target pieces.

Each of the first target pieces is bonded to the second target pieces, and hence when the second target pieces are removed by the hydrogen embrittlement process, it is possible to separate the first target portion for each of the first target pieces.

The first material may include a first kind of material including a first element, and a second kind of material including a second element different from the first element, and the plurality of first target pieces may include a target piece made of the first kind of material, and a target piece made of the second kind of material.

By using the first target pieces of a plurality of kinds including different constituent materials, it is possible to constitute the first target portion of a plurality of materials. By the hydrogen embrittlement process, the first target portion is separated for each of the first target pieces, and hence even in the case where the first target portion is made of the plurality of materials, it is possible to collect the first material by kind.

The first kind of material may be any one of Al, Cu, W, Mo, Pt, and Cr, and the second kind of material may be any one of Ti, Zr, Fe, Ni, Ta, and Nb.

### First Embodiment

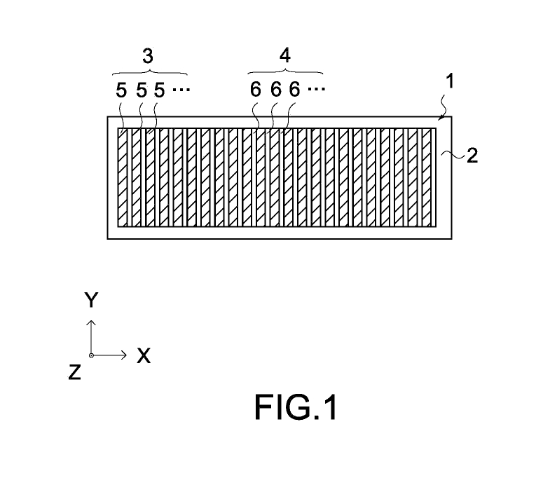

FIG. 1 is a plane view showing a sputtering target (hereinafter, referred to as target) 1 according to this embodiment. The drawing shows the target 1 as viewed from a surface to be sputtered side. It should be noted that, in each of the following drawings, one direction parallel to the surface to be sputtered is referred to as an X-direction, a direction parallel to the surface to be sputtered, but perpendicular to the X-direction is referred to as a Y-direction, and a direction perpendicular to the X-direction and the Y-direction is referred to as a Z-direction.

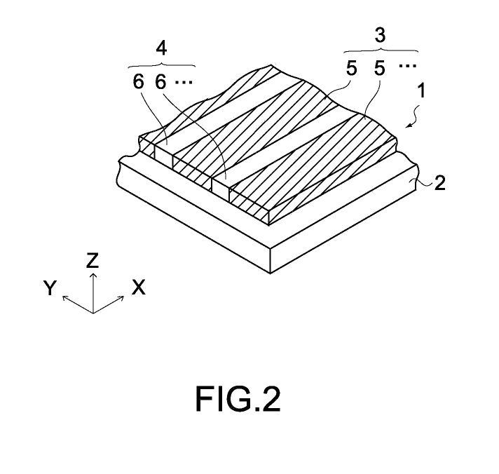

FIG. 2 is a perspective view showing a part of the target 1 in an enlarged state.

As shown in those drawings, the target 1 is bonded on a backing plate 2.

The backing plate 2 holds the target 1 and cools this, and further, functions as an electrode. The material of the backing plate 2 is not particularly limited, and can be, for example, Cu.

The target 1 includes a first target portion 3 and a second target portion 4. The target 1 is bonded to the backing plate 2 by a method such as soldering and soldering or mechanical holding. The top surface (surface in opposite to a surface bonded on the backing plate 2) of the target 1 is set as the surface to be sputtered.

The target 1 is, as will be described later, constituted of two kinds of target pieces made of different constituent metals. The target 1 includes a first target piece 5 made of a non hydrogen embrittlement material and a second target piece 6 made of a hydrogen embrittlement material. That is, the target 1 is a target for forming a thin film including those materials as components.

The first target portion 3 is constituted of a plurality of first target pieces 5, and forms a part of the surface to be sputtered. The material of the first target pieces 5 can be selected from non hydrogen embrittlement materials (materials not to be hydrogen-embrittled) including metals such as Al, Cu, W, Mo, Pt, Cr, and the like, the alloys and oxides thereof, and the like. The material selected as the material of the first target portion 3 is referred to as a first material. The first material according to this embodiment is composed of a single kind of material, and all of the first target pieces 5 are composed of such a kind of material. For example, each of the first target pieces 5 has a rectangular plate-like shape having long sides in the X-direction and short sides in the Y-direction. The first target pieces 5 are all formed to have the same size.

The second target portion 4 is constituted of a plurality of second target pieces 6, and forms a part of the surface to be sputtered. The material of the second target pieces 6 can be selected from hydrogen embrittlement materials (materials to be hydrogen-embrittled) including metals such Ti, Zr, Fe, Ni, Ta, Nb, and the like, the alloys and oxides thereof, and the like. The material selected as the material of the second target portion 4 is referred to as a second material. For example, each of the second target pieces 6 has a rectangular plate-like shape having long sides of the same length as those of the first target piece 5 in the X-direction and short sides in the Y-direction. The second target pieces 6 are all formed to have the same size.

It should be noted that the combination of the first material and the second material is selected depending on the elemental composition of an alloy thin film to be produced.

The first target pieces 5 and the second target pieces 6 are alternately arranged in the X-direction. The size, the arranged number, and the like of the first target pieces 5 and the second target pieces 6 can be changed appropriately. The size of the first target pieces 5 and the second target pieces 6 defines the area that is occupied by the first target portion 3 and the second target portion 4 in the surface to be sputtered of the target 1. That is, it is possible to control the compositional ratio of the alloy to be formed as a film in the sputtering.

The first target pieces 5 are bonded to the second target pieces 6 adjacent thereto, and the second target pieces 6 are bonded to the first target pieces 5 adjacent thereto. The first target pieces 5 and the second target pieces 6 are also bonded to the backing plate 2. Although the bonding method is not limited to the soldering, the diffusion bonding, and the like, the diffusion bonding can prevent generation of particles due to arc discharge occurring in clearances between the target pieces and concentration of stress due to difference of coefficient of thermal expansion.

Next, a method of manufacturing the target 1 according to this embodiment will be described.

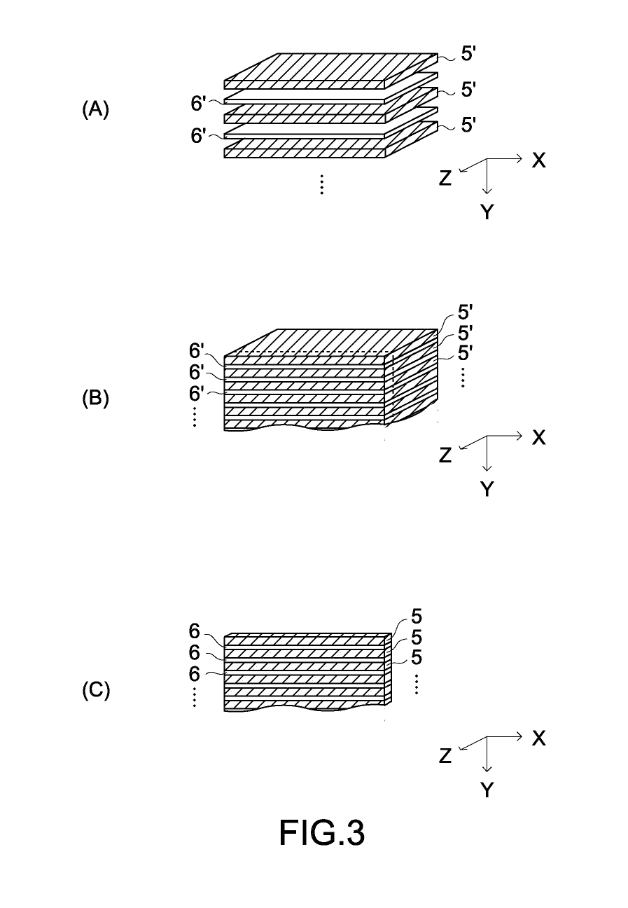

FIG. 3 are views describing a method of manufacturing the target 1.

A plurality of first plates 5′ made of the first material and a plurality of second plates 6′ made of the second material are prepared. The first plates 5′ and the second plates 6′ can be produced by methods, for example, melting and casting, and sintering. Each of the first plates 5′ may have a rectangular shape having a thickness (Y-direction) having the same length as that of each of the short sides of the first target pieces 5 and one sides (X-direction) each having the same length as that of each of the long sides of the first target pieces 5. Each of the second plates 6′ may have a rectangular shape having a thickness (Y-direction) having the same length as that of each of the short sides of the second target pieces 6 and one sides (X-direction) each having the same length as that of each of the long sides of the second target pieces 6.

Next, as shown in FIG. 3(A), the plurality of first plates 5′ and second plates 6′ are alternately stacked and bonded in the Y-direction. This may be performed by the diffusion bonding, for example. When pressure is applied on the first plates 5′ and the second plates 6′ in the Y-direction, the first plates 5′ and the second plates 6′ can be bonded to each other with an adequate strength.

Next, as shown in FIG. 3(B), the first plates 5′ and the second plates 6′ are cut in a plane in parallel to the X-Y plane, which is shown by the broken line in FIG. 3(B). For example, mechanical cutting can be used for bonding. With the cutting in the above-mentioned manner, the first plates 5′ and the second plates 6′ are obtained as a result of the cutting and the first target pieces 5 and the second target pieces 6 which are alternately arranged are formed.

In this manner, as shown in FIG. 3(C), a plate to be a target is cut out. When such a plate is bonded to the backing plate, the target 1 is manufactured. When the target 1 is manufactured in this manner, the bonding strength of the first target pieces 5 and the second target pieces 6 can be increased as compared to a case of bonding the end surfaces of the first target pieces 5 and the second target pieces 6.

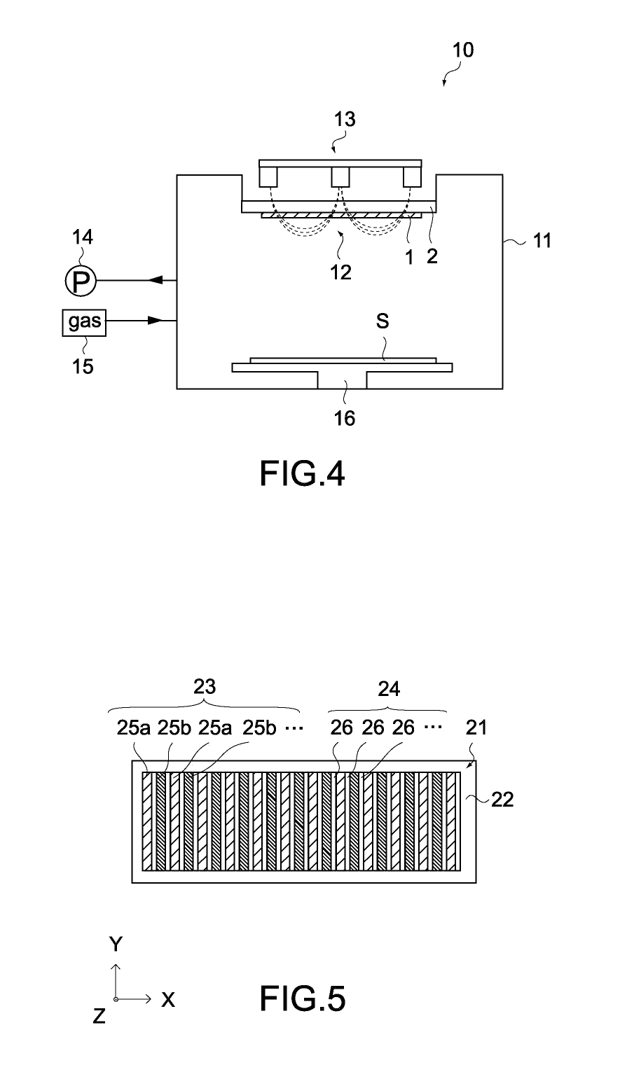

Next, sputtering using the target 1 will be described. The target 1 according to this embodiment can be subjected to various sputtering processes (AC (Alternating Current) process, DC (Direct Current) process, RF (radio frequency) process, magnetron process, and the like). Here, a case where the target 1 is subjected to the magnetron sputtering process is illustrated. FIG. 4 is a view showing a schematic configuration of a sputtering apparatus 10.

As shown in the drawing, the sputtering apparatus 10 includes a chamber 11, a sputter cathode 12 arranged in the inside of the chamber 11, and a magnetic-field forming portion 13 for forming a magnetic field distribution, the magnetic-field forming portion 13 being arranged in vicinity of the sputter cathode 12. The sputter cathode 12 includes the target 1. Further, within the chamber 11, a substrate S is placed.

To the chamber 11, a vacuum pumping system 14 that evacuates the chamber 11 and a gas introducing system 15 that introduces process gas into the chamber 11 are connected. Further, in the inside of the chamber 11, a stage 16 to be an anode, that supports the substrate S, is provided. The substrate S is arranged so as to be opposed to the sputter cathode 12.

The sputter cathode 12 is constituted of the target 1 and the backing plate 2. On a surface (back surface) side in opposite to the surface (top surface) side, on which the target 1 is bonded, of the backing plate 2, the magnetic-field forming portion 13 is arranged. The magnetic-field forming portion 13 forms the magnetic field distribution as shown in FIG. 4 in vicinity of the top surface of the target 1.

In the sputtering with the sputtering apparatus 10, first, the chamber 11 is evacuated, and then, the process gas such as Ar is introduced into the chamber 11. Next, voltage is applied between the sputter cathode 12 and the stage 16 being the anode, and the magnetic-field forming portion 13 forms the magnetic field in vicinity of the sputter cathode 12. Due to the electric field and the magnetic field, the process gas is converted into plasma. By collision of ions against the top surface of the target 1, the sputtering is performed.

The first material scatters from the first target portion 3 of the target 1 as sputter particles and the second material scatters from the second target portion 4 as sputter particles, and are deposited on the substrate S as an alloy of the first material and the second material. Depending on the area occupied by the first target portion 3 and the second target portion 4 in the surface to be sputtered of the target 1, the composition of an alloy to be deposited is controlled.

Positions at which the ions of the process gas collide with the surface to be sputtered of the target 1 is influenced by a magnetic field forming position or the like, and hence the positions are not uniform on the surface to be sputtered. As the sputtering proceeds, on the surface to be sputtered, an erosion region in which the ions collide with the surface to be sputtered frequently, and hence degree of wear of the target material is high and a non-erosion region in which the degree of wear of the target material is low. When the thickness of the target material corresponding to the erosion region is decreased, even if an adequate amount of target material corresponding to the non-erosion region remains, the target has to be exchanged. That is, in the exchanged target, the target material still remains, and such a target material can be recycled. It should be noted that the non-erosion region generates also during sputtering processes other than the magnetron sputtering.

Next, a method of collecting the first material and the second material from the target 1 will be described.

The target 1 subjected to the sputtering is removed from the backing plate 2. The target 1 is removed, for example, by heating it to above the melting point of the soldering material.

Next, the target 1 subjected to the sputtering is subjected to a hydrogen embrittlement process. The target 1 is placed in a processing chamber, the processing chamber is evacuated, and then hydrogen gas is introduced. The hydrogen gas is introduced until a pressure equal to or higher than the atmospheric pressure is obtained, for example.

Next, the target 1 is heated. The heating is kept at a temperature (first temperature) (for example, 600° C.), at which hydrogen can be absorbed by the second material, for a predetermined period of time. The first temperature is regulated depending on the kind of the second material.

Next, the heating temperature is changed to a second temperature lower than the first temperature. The second temperature is set to a temperature at which the hydrogen absorbed by the second material at the first temperature is gasified, and is regulated depending on the kind of the second material. When the target 1 is kept at the second temperature (for example, 420° C.) for a predetermined period of time, the hydrogen absorbed by the second material is gasified and the second target portion 4 is brittle-fractured. As described above, the target 1 is subjected to the hydrogen embrittlement process. It should be noted that the hydrogen embrittlement process is not limited to the one that is described above.

Next, the first material and the second material are collected. By the hydrogen embrittlement process, the first material that had been the second target portion 4 is fractured, and the first material that had been the first target portion 3 keeps the shapes of the first target pieces 5. Therefore, the first material and the second material can be readily separated from each other.

The second material is collected by collecting the fractured pieces, and the first material is collected as the first target pieces 5. Regarding the first target pieces 5 separated from the target 1, there is a case where the second material adheres to or is dispersed in portions in which the first target pieces 5 had been bonded to the second target pieces 6. In this case, through removing such a second material by a blast process, mechanical polishing, or the like, the first material with high purity can be collected.

In this manner, the first material and the second material are collected. By utilizing the hydrogen embrittlement process, irrespective of the bonding strength of the first target pieces 5 and the second target pieces 6, the first material and the second material can be collected in a highly pure state.

As described above, the constituent materials of the target according to this embodiment can be collected by the processing method according to this embodiment in high recycling efficiency.

### Second Embodiment

Hereinafter, the second embodiment will be described. The second embodiment is different from the first embodiment in that the first target portion is made of two or more kinds of materials in the second embodiment. It should be noted that the descriptions of the duplicated points with respect to the content described in the first embodiment will be omitted.

FIG. 5 is a plane view showing a target 21 according to this embodiment. The drawing shows the target 21 as viewed from a surface to be sputtered side.

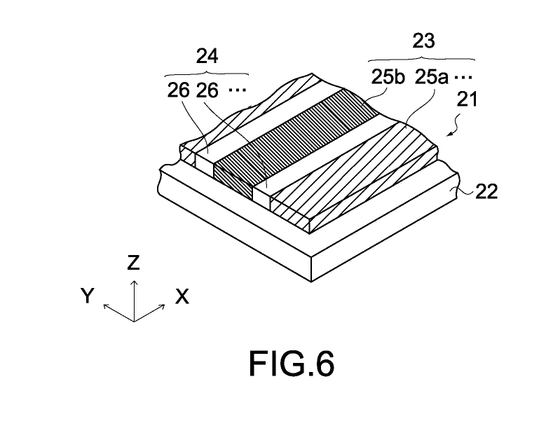

FIG. 6 is a perspective view showing a part of the target 21 in an enlarged state.

As shown in those drawings, the target 21 is bonded on a backing plate 22.

The target 21 includes a first target portion 23 and a second target portion 24. The target 21 is bonded to the backing plate 22 by a method such as soldering or mechanical holding. The top surface (surface in opposite to a surface bonded on the backing plate 22) of the target 21 is set as the surface to be sputtered.

The target 21 is, as will be described later, constituted of three kinds of target pieces made of different constituent metals. The target 21 includes a first target pieces 25a made of a non hydrogen embrittlement material, a first target pieces 25b made of a non hydrogen embrittlement material different from the non hydrogen embrittlement material of the first target pieces 25a, and a second target piece 26 made of a hydrogen embrittlement material. That is, the target 21 is a target for forming a thin film including those materials as components.

The first target portion 23 is constituted of a plurality of first target pieces 25, and forms a part of the surface to be sputtered. The material of the first target pieces 25 can be selected from non hydrogen embrittlement materials (materials not to be hydrogen-embrittled) including metals such as Al, Cu, W, Mo, Pt, Cr, and the like, the alloys and oxides thereof, and the like. The material selected as the material of the first target portion 23 is referred to as a first material. The first material according to this embodiment includes two kinds of materials (first kind of material and second kind of material). Of the first target pieces 25, those that are made of the first kind of material are referred to as the first target pieces 25a and those that are made of the second kind of material are referred to as the first target pieces 25b. For example, each of the first target pieces 25 has a rectangular plate-like shape having short sides in the X-direction and long sides in the Y-direction. The first target pieces 25a and the first target pieces 25b are formed to have the same length in the long sides. The short sides of the first target pieces 25a and the first target pieces 25b may be formed to have the same length, or may be formed to have different lengths.

The second target portion 24 is constituted of a plurality of second target pieces 26, and forms a part of the surface to be sputtered. The material of the second target pieces 26 can be selected from hydrogen embrittlement materials (materials to be hydrogen-embrittled) including metals such Ti, Zr, Fe, Ni, Ta, Nb, and the like, the alloys and oxides thereof, and the like. The material selected as the material of the second target portion 24 is referred to as a second material. For example, each of the second target pieces 26 has a rectangular plate-like shape having short sides in the X-direction and long sides in the Y-direction, the long sides having the same length as those of the first target piece 5. The second target pieces 26 are all formed to have the same size.

It should be noted that the combination of the first material and the second material is selected depending on the elemental composition of an alloy thin film to be produced.

The first target pieces 25 and the second target pieces 26 are alternately arranged in the X-direction. It should be noted that regarding the first target pieces 25, the first target pieces 25a and the first target pieces 25b are alternately arranged. The size, the arranged number, and the like of the first target pieces 5 and the second target pieces 6 can be changed appropriately. The size of the first target pieces 25a, the first target pieces 25b, and the second target pieces 26 defines the area that is occupied by the first target portion 23 and the second target portion 24 in the surface to be sputtered of the target 1. That is, it is possible to control the compositional ratio of the alloy to be formed as a film in the sputtering.

The first target pieces 25 are bonded to the second target pieces 26 adjacent thereto, and the second target pieces 26 are bonded to first target pieces 25 adjacent thereto. The first target pieces 25 and the second target pieces 26 are also bonded to the backing plate 22. Although the bonding method is not limited to the soldering, the diffusion bonding, and the like, the diffusion bonding can prevent generation of particles due to arc discharge occurring in clearances between the target pieces and concentration of stress due to difference of coefficient of thermal expansion.

Next, a method of manufacturing the target 1 according to this embodiment will be described.

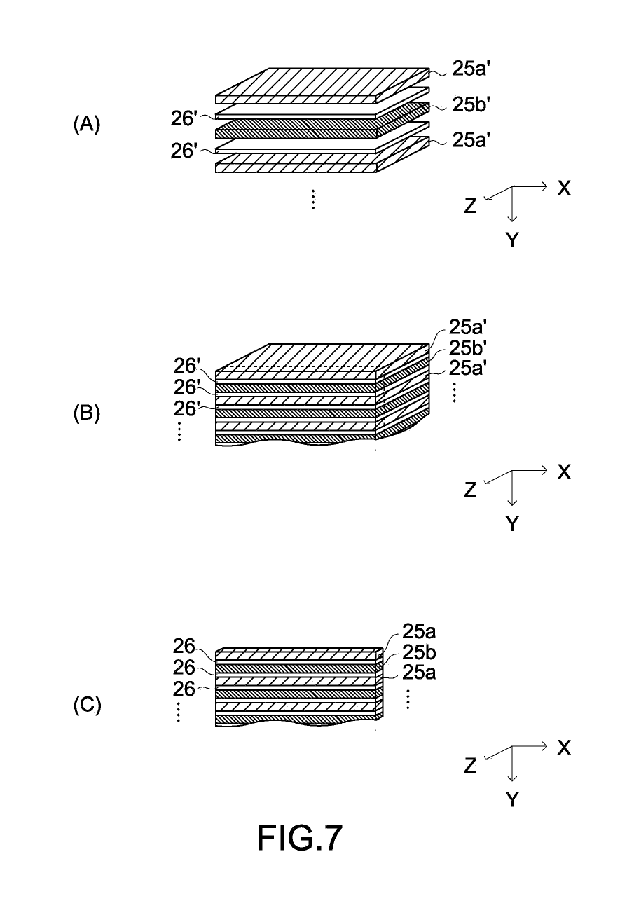

FIG. 7 are views describing a method of manufacturing the target 1.

A plurality of first plates 25a′ made of the first kind of material and a plurality of first plates 25b′ made of the second kind of material, and a plurality of second plates 26′ made of the second material are prepared. The first plates 25a′, the first plates 25b′, and the second plates 26′ can be produced by methods, for example, melting and casting, and sintering. Each of the first plates 25a′ may have a rectangular shape having a thickness (Y-direction) having the same length as that of each of the short sides of the first target pieces 25a and one sides (X-direction) each having the same length as that of each of the long sides of the first target pieces 25. Each of the first plates 25b′ can have a rectangular shape having a thickness (Y-direction) having the same length as that of each of the short sides of the first target pieces 25b and one sides (X-direction) each having the same length as that of each of the long sides of the first target pieces 25b. Each of the second plates 26′ can have a rectangular shape having a thickness (Y-direction) having the same length as that of each of the short sides of the second target pieces 26 and one sides (X-direction) each having the same length as that of each of the long sides of the second target pieces 26.

Next, as shown in FIG. 7(A), the plurality of first plates 25a′, the plurality of first plates 25b′, and the plurality of second plates 26′ are stacked and bonded in the Y-direction. Here, the stacking is performed in such a manner that the first plates 25a′ and the first plates 25b′ are alternately arranged and each of the second plates 26′ is interposed between the first plate 25a′ and the first plate 25b′. This may be performed by the diffusion bonding, for example. When pressure is applied on the first plates 25a′, the first plates 25b′, and the second plates 26′ in the Z-direction, the first plates 25a′, the first plates 25b′, and the second plates 26′ can be bonded to each other with an adequate strength.

Next, as shown in FIG. 7(B), the first plates 25a′, the first plates 25b′, and the second plates 26′ are cut in a plane in parallel to the X-Y plane, which is shown by the broken line in FIG. 7(B). For example, mechanical cutting can be used for bonding. With the cutting in the above-mentioned manner, the first plates 25a′, the first plates 25b′, and the second plates 26′ are cut out so that the first target pieces 25 and the second target pieces 26 which are alternately arranged are formed.

In this manner, as shown in FIG. 7(C), a plate to be a target is obtained as a result of the cutting. When such a plate is bonded to the backing plate, the target 21 is manufactured. When the target 21 is manufactured in this manner, the bonding strength of the first target pieces 25 and the second target pieces 26 can be increased as compared to a case of bonding each of the first target pieces 25 and each of the second target pieces 26 to each other at the surfaces thereof.

Next, a method of collecting the first material (first kind of material, second kind of material) and the second material from the target 21 will be described.

The target 21 subjected to the sputtering is removed from the backing plate 22. Most of the target 21 is removed, for example, by heating it to above the melting point of the soldering material. After that, the soldering material is completely removed by etching.

Next, the target 21 subjected to the sputtering is subjected to a hydrogen embrittlement process. The target 21 is placed in the processing chamber, the processing chamber is evacuated, and then hydrogen gas is introduced. The hydrogen gas is introduced until a pressure equal to or higher than the atmospheric pressure is obtained, for example.

Next, the target 21 is heated. The heating is kept at a temperature (first temperature) (for example, 600° C.), at which hydrogen can be absorbed by the second material, for a predetermined period of time. The first temperature is regulated depending on the kind of the second material.

Next, the heating temperature is changed to a second temperature lower than the first temperature. The second temperature is set to a temperature at which the hydrogen absorbed by the second material at the first temperature is gasified, and is regulated depending on the kind of the second material. When the target 1 is kept at the second temperature (for example, 420° C.) for a predetermined period of time, the hydrogen absorbed by the second material is gasified and the second target portion 24 is brittle-fractured. As described above, the target 1 is subjected to the hydrogen embrittlement process. It should be noted that the hydrogen embrittlement process is not limited to the one that is described above.

Next, the first material (first kind of material, second kind of material) and the second material are collected. By the hydrogen embrittlement process, the first material that had been the second target portion 24 is fractured, and the first material that had been the first target portion 23 keeps the shapes of the first target pieces 25a and the first target pieces 25b. Therefore, the first material and the second material can be readily separated from each other. Also in the case where the first material is constituted of a plurality of kinds of materials (first kind of material, second kind of material), one target piece is formed for one kind of material, and hence the separation for each target piece can be performed.

The second material is collected by collecting the fractured pieces, and the first material is collected as the first target pieces 25. Regarding the first target pieces 25 separated from the target 1, there is a case where the first material adheres to or is dispersed in portions in which the first target pieces 25 had been bonded to the second target pieces 26. In this case, through removing such a first material by a blast process, mechanical polishing, or the like, the first material with high purity can be collected.

In this manner, the first material (first kind of material, second kind of material) and the second material are collected. By utilizing the hydrogen embrittlement process, irrespective of the bonding strength of the first target pieces 25 and the second target pieces 26, the first material and the second material can be collected in a highly pure state.

As described above, the constituent materials of the target according to this embodiment can be collected by the processing method according to this embodiment in high recycling efficiency. Further, although in this embodiment the first material includes two kinds of materials, the present invention is not limited thereto, but three or more kinds of materials may be included. Also in this case, by utilizing the hydrogen embrittlement process, the separation for each kind of material can be performed.

### Example

Hereinafter, an example will be described.

This example relates to a target for forming a film of a Ti—W alloy (Ti 10%, W 90%) on the substrate.

The first target portion was set to be made of W (first material) being the non hydrogen embrittlement material, and the second target portion was set to be made of Ti (second material) being the hydrogen embrittlement material.

With reference to FIG. 3, a method of manufacturing the target will be described.

39 plates (first plates 5′) made of W, that has one sides (X-direction) of 130 mm, the other sides (Z-direction) of 100 mm, and a thickness (Y-direction) of 7 mm and plates (second plates 6′) made of Ti, that has one sides (X-direction) of 130 mm, the other sides (Z-direction) of 100 mm, and a thickness (Y-direction) of 3 mm were stacked on each other as shown in FIG. 3(A), and were diffusion-bonded to each other. For the diffusion bonding, a vacuum hot-pressing process was used, and under pressure lower than 5.0×10⁻³ Pa, pressure of 300 to 400 kg/cm² was applied at 1300 to 1400° C. As a result, as shown in FIG. 3(B), a block having one side (X-direction) of 130 mm, the other side (Z-direction) of 100 mm, and a thickness (Y-direction) of 390 mm was formed.

Next, as shown by the broken line in FIG. 3(B), such a block was cut out by the cutting to have a thickness of 6 mm (Z-direction). As a result of the cutting, as shown in FIG. 3(C), a plate to be a target was obtained, that has long sides (Y-direction) of 390 mm, short sides (X-direction) of 130 mm, and a thickness (Z-direction) of 6 mm. Such a plate was bonded to the backing plate with a soldering material such as In, so that the target was obtained.

Sputtering using the target produced in the above-mentioned manner will be described.

The target was attached to the sputtering apparatus, the schematic configuration of which is shown in FIG. 4, and the sputtering was carried out. The sputtering condition was set so that the applied voltage was 3.5 kV, and the pressure was 7×10⁻³.

After the sputtering, a thin film made of the Ti—W alloy and having a uniform composition was formed on the substrate.

A method of collecting W (first material) and Ti (second material) from the target subjected to the sputtering will be described.

The used target was heated up to 200° C., to thereby melt the soldering material made of In. In this manner, the used target was removed from the backing plate. After that, etching was performed for removing the soldering material. The used target was placed in the processing chamber, and the processing chamber was evacuated. Hydrogen gas was introduced into the processing chamber so that the processing chamber is pressurized up to 1.2 atmospheres. In this 100% hydrogen atmosphere, the target was heated up to 600° C., and kept for 1 hour. After that, the heating temperature of the target was changed to 420° C., and kept for 14 hours (hydrogen embrittlement process).

By the above-mentioned hydrogen embrittlement process, Ti was fractured due to the hydrogen embrittlement, and W was collected in its original target piece form. The collected W exhibits a high purity, and, for example, this W can be used as a raw material of a W target.

The present invention is not limited to the above-mentioned embodiments, and can be changed without departing from the gist of the present invention.

(Modification 1)

Modification 1 of the present invention will be described.

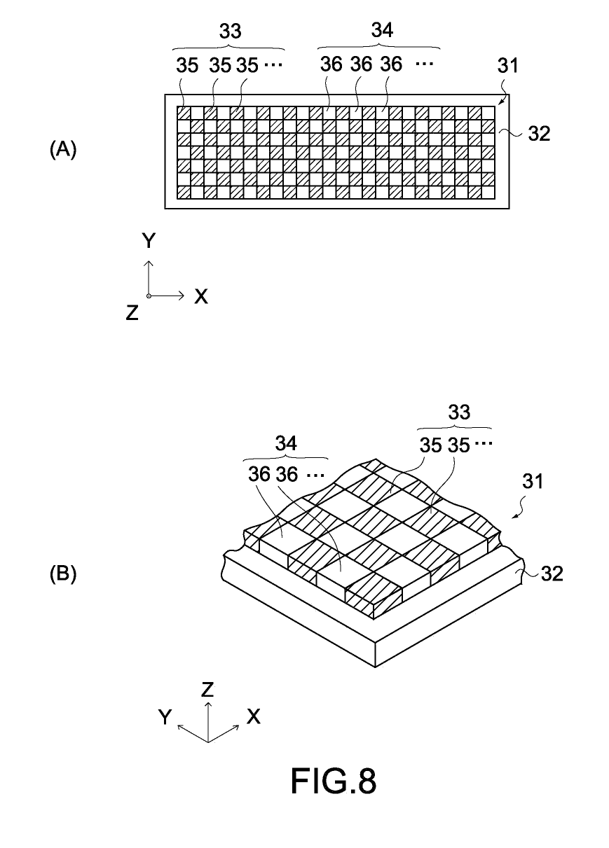

FIG. 8 are views showing a target 31 according to Modification 1.

FIG. 8(A) is a plane view as the target 31 is viewed from a surface to be sputtered side, and FIG. 8(B) is a perspective view showing a part of the target 31 in an enlarged state.

As shown in the drawings, the target 31 is constituted of a first target portion 33 made of a plurality of first target pieces 35 each shaped into a quadrate and a second target portion 34 made of a plurality of second target pieces 36 each shaped into a quadrate, and is bonded on a backing plate 32. The first target pieces 35 and the second target pieces 36 are arranged in a checkerboard pattern to prevent the first target pieces 35 from being adjacent to each other and to prevent the second target pieces 36 from being adjacent to each other. It should be noted that the first target portion 33 may be made of two or more kinds of materials (first kind of material and second kind of material). In this case, the first target pieces 35 made of the first kind of material, and the first target pieces 35 made of the second kind of material are alternately arranged via the second target pieces 36. When the target 31 is subjected to the hydrogen embrittlement process as described above, the second target pieces 36 are brittle-fractured, and the first target pieces 35 remain while keeping their own shapes. Thus, it is possible to effectively separate the first material and the second material from each other, to thereby collect them.

(Modification 2)

Modification 2 of the present invention will be described.

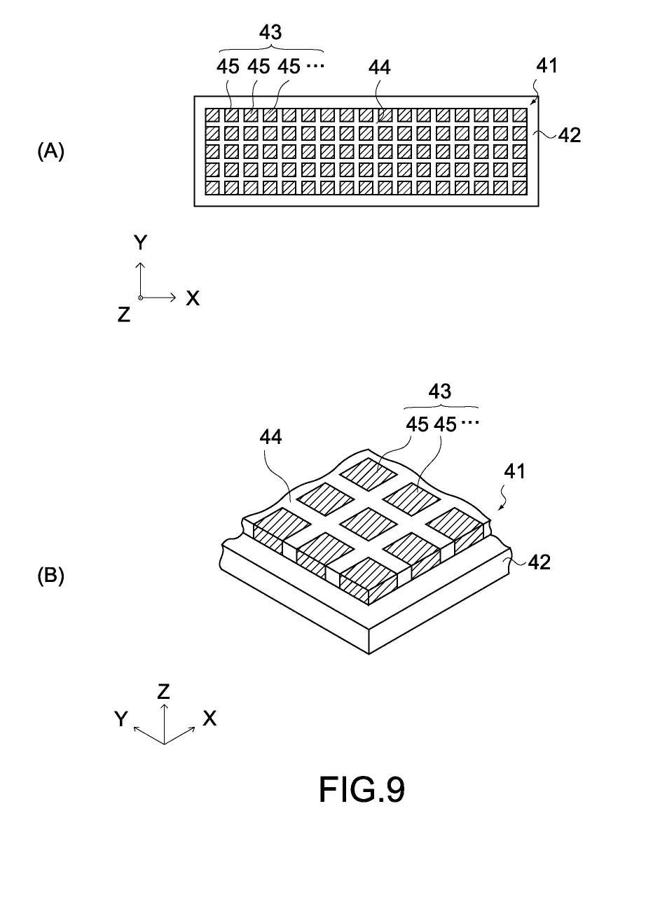

FIG. 9 are views showing a target 41 according to Modification 2.

FIG. 9(A) is a plane view as the target 41 is viewed from a surface to be sputtered side, and FIG. 9(B) is a perspective view showing a part of the target 41 in an enlarged state.

As shown in the drawings, the target 41 is constituted of a first target portion 43 made of a plurality of first target pieces 45 each shaped into a quadrate and a second target portion 44 made of a single member having a grid shape, and is bonded on a backing plate 42. Each of the first target pieces 45 is fitted into each of holes in the grid of the second target portion 44, and is bonded to the second target portion 44 surrounding such a first target piece 45. Each of the first target pieces 45 is isolated by the second target portion 44 from the other first target pieces 45. It should be noted that the first target portion 43 may be made of two or more kinds of materials (first kind of material and second kind of material). In this case, the first target pieces 45 made of the first kind of material, and the first target pieces 45 made of the second kind of material are alternately arranged via the second target portion 44. When the target 41 is subjected to the hydrogen embrittlement process as described above, the second target portion 44 is brittle-fractured, and the first target pieces 45 remain while keeping their own shapes. Thus, it is possible to effectively separate the first material and the second material from each other, to thereby collect them.

(Modification 3)

Modification 3 of the present invention will be described.

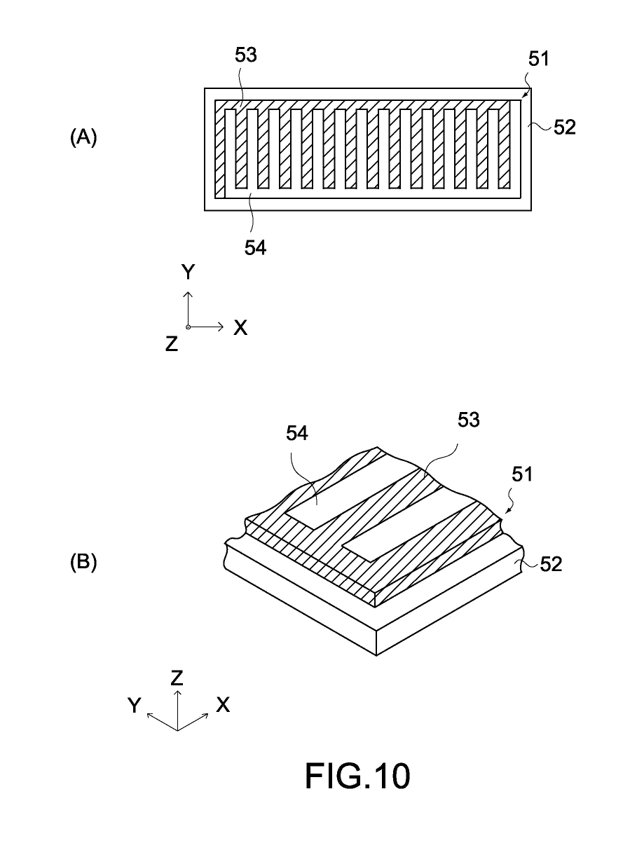

FIG. 10 are views showing a target 51 according to Modification 3.

FIG. 10(A) is a plane view as the target 51 is viewed from a surface to be sputtered side, and FIG. 10(B) is a perspective view showing a part of the target 51 in an enlarged state.

As shown in the drawings, the target 51 is constituted of a first target portion 53 made of a single member having a comb shape and a second target portion 54 made of a single member having a comb shape, and is bonded to a backing plate 52 in such a manner that the tines of one comb are fitted into corresponding parts of the other comb. With this structure, the alloy composition of the first material and the second material can be made to be uniform. When the target 51 is subjected to the hydrogen embrittlement process as described above, the second target portion 54 is brittle-fractured, and the first target piece 55 remains while keeping its own shape. Thus, it is possible to effectively separate the first material and the second material from each other, to thereby collect them.

Although in each of the above-mentioned embodiments the example in which the target is rectangular is shown, the present invention is not limited thereto, but a circular shape and other shapes can be employed. Further, the target is not limited to being plane, but the target may have a solid shape such as a cylinder shape.

### DESCRIPTION OF REFERENCE NUMERALS

1 sputtering target
2 backing plate
3 first target portion
4 second target portion
5 first target piece
6 second target piece
21 target
22 backing plate
23 first target portion
24 second target portion
25 first target piece
26 second target piece
31 target
32 backing plate
33 first target portion
34 second target portion
35 first target piece
36 second target piece
41 target
42 backing plate
43 first target portion
44 second target portion
45 first target piece
51 target
52 backing plate
53 first target portion
54 second target portion
55 first target piece

1. A method of processing a sputtering target, comprising:
performing a hydrogen embrittlement process with respect to a sputtering target including a first target portion made of a first material being a non hydrogen embrittlement material and a second target portion made of a second material being a hydrogen embrittlement material, which are bonded to each other, to thereby separate from the sputtering target the second target portion;
collecting the second material; and
collecting the first material.

2. The method of processing the sputtering target, according to claim 1, wherein
the step of performing the hydrogen embrittlement process includes keeping the sputtering target in the hydrogen atmosphere at a first temperature, and then changing the first temperature to a second temperature lower than the first temperature.

3. A sputtering target including a surface to be sputtered, for forming a thin film made of an alloy, comprising:
a first target portion that is made of a first material being a non hydrogen embrittlement material not to be embrittled in hydrogen atmosphere, and forms a part of the surface to be sputtered; and
a second target portion that is made of a second material being a hydrogen embrittlement material to be embrittled in the hydrogen atmosphere, is bonded to the first target portion, and forms another part of the surface to be sputtered.

4. The sputtering target according to claim 3, wherein
the first target portion is made of a plurality of first target pieces,
the second target portion is made of a plurality of second target pieces, and
between the plurality of first target pieces, each of the second target pieces is interposed.

5. The sputtering target according to claim 4, wherein
the first material includes
a first kind of material including a first element, and
a second kind of material including a second element different from the first element, and
the plurality of first target pieces include
a target piece made of the first kind of material, and
a target piece made of the second kind of material.

6. The sputtering target according to claim 5, wherein
the first kind of material is any one of Al, Cu, W, Mo, Pt, and Cr, and
the second kind of material is any one of Ti, Zr, Fe, Ni, Ta, and Nb.
